(19) United States
(12) Patent Application Publication
(10) Pub. No.: US 2006/0202590 A1
(43) Pub. Date: Sep. 14, 2006

(54) Low cost SH-saw fluid flow sensor

(75) Inventors: James Zt Liu, Belvidere, IL (US); Richard A. Alderman, Freeport, IL (US)

Correspondence Address: Kris T. Fredrick;Intellectual Property Honeywell Intr., Inc., 101 Columbia Rd., P.O. Box 2245, Morristown, NJ, 07962, US

(73) Assignee: Honeywell International, Inc.

(21) Appl. No.: 11/077,143

(22) Filed: Mar. 9, 2005

(51) Int. Cl. H01L 41/00

(52) U.S. Cl. 310/338

(57) ABSTRACT

A SH-SAW based fluid flow sensor module is disclosed. The sensor module is inexpensive and disposable because it does not include any of the circuitry required for driving, powering, or reading the sensor module. The sensor module can be driven, powered, and read using either wired or wireless connections. Additionally, other sensor types, such as SAW based pressure or chemical sensors, can be integrated into the sensor module.

### TECHNICAL FIELD

Embodiments relate to the field of fluid flow sensing. Embodiments also relate to surface acoustic wave devices wherein the acoustic waves are either Shear-Horizontal (SH) mode or guided SH mode and the use of those devices is for measuring fluid flows. The fluid flow sensor module disclosed can be connected to external circuitry using either a wired or wireless connection.

### BACKGROUND OF THE INVENTION

Many flow sensors are based on the rate at which flowing gases or fluids transport heat away from a heated sensor. The sensor is heated and its temperature is measured. Lower temperatures correlate with higher fluid flow rates. In the past a heated wire element was commonly used.

A surface acoustic wave device (SAW) is a device that has at least one transducer and a substrate. An input electrical signal is converted to an acoustic signal by the transducer. The acoustic signal propagates through the substrate and along the substrate surface. Eventually, a transducer converts the acoustic signal into an output electric signal. Stress, flex, and dimensional changes of the substrate cause changes in the acoustic signal. Processing the output electrical signal can yield the details of processes or environmental conditions that caused any stress, flex, or dimensional changes. In most devices there are separate input and output transducers. SAW devices have many uses. Recently, SAWs have been used to measure gas flow rates. The details of SAW based gas flow sensors are well known.

FIG. 1, labeled as prior art, shows an acoustic wave 102 traveling through a substrate 101 in the propagation direction 105. It has two components. One component is normal 103 to the substrate surface 106 and the other is parallel 104 to the substrate surface 106. The component normal 103 to the surface has R mode propagation. The component parallel 104 to the surface has SH mode propagation. FIG. 1 shows a predominantly Rayleigh mode acoustic wave 102. Other terms for Rayleigh mode are R mode and Surface mode.

FIG. 2, labeled as prior art, shows an acoustic wave 201 traveling through a substrate 101 in the propagation direction 105. It also has two components. FIG. 2 shows a predominantly SH mode acoustic wave 201.

FIG. 3, labeled as prior art, shows a SAW based sensor using transducers that have a serpentine pattern 304. The transducers can be formed on a substrate 101 using standard photolithographic processing. The input transducer 301 has two pads 303 that are used to couple an electric signal into the transducer. The output transducer 304 also has two pads 303, but uses them to couple an electric signal out of the transducer. This device can be used to measure temperature because temperature causes the substrate to grow, contract, or otherwise undergo stress. Changes to the substrate cause it to conduct acoustic signals differently. Processing the signal coupled into the input transducer 301 and the signal coupled out of the output transducer 302 yields the temperature.

FIG. 4, labeled as prior art, shows a SAW based sensor using transducers that have an interdigitated pattern 403. It also has an input transducer 401 and an output transducer 402. It is operationally similar to the device of FIG. 3. The use and fabrication of devices such as those shown in FIG. 3 and FIG. 4 are known to those skilled in the art of SAW devices. Furthermore, photolithographic processing is one of the many processing techniques for producing patterned structures on a substrate. Another possibility is direct printing using conductive ink. Those skilled in the art of SAW devices know these and many other ways to produce SAW devices.

The components of an acoustic wave propagate differently based on the substrate and environmental factors. One of the differences is how quickly each mode is extinguished. In many SAW devices, a property of the substrate is that SH mode propagation is extinguished quickly while Rayleigh mode propagation is extinguished far slower. Environmental factors also play an important role. Submerging most SAW devices in a fluid causes Rayleigh mode propagation to be quickly extinguished but has little effect on SH mode propagation. The result is that, for most submerged SAW devices, SH mode propagation is quickly extinguished by the substrate and Rayleigh mode propagation is quickly extinguished by the fluid. Most SAW devices cannot be used while submerged in a fluid.

A type of SAW, called an SH-SAW, can be made such that the substrate does not quickly extinguish the SH mode propagation. SH-SAW based sensors have been used to measure fluid properties such as acoustic properties and pressure. SH-SAW based sensors have been used to identify fluids and detect chemicals. However, SH-SAWs have not been used to measure fluid flow. Another type of SAW is the guided SH-SAW that is essentially a SH-SAW with a coating. Guided SH-SAW based sensors are also known as Love wave devices. Those skilled in the art of SAW devices are aware of the properties and use of both SH-SAW and guided SH-SAW.

The methods for producing SAW devices, including SH-SAW and guided SH-SAW are well known amongst those skilled in the art of SAW devices. Generally, a thin layer of metal is deposited on a substrate. Standard lithographic processes are then used to form the metal into transducers for the SAW device. Elements other than transducers can also be formed on the substrate. For example, through standard lithographic processes the transducers can be masked off, a second metal deposited, masked, and etched to from a heater.

An advantage of all SAW type devices is that they are easy and inexpensive to manufacture. However, a SAW is not useful in isolation. External electronic circuitry is required to power and deliver input signals to the SAW and to receive output signals. The electronic circuitry required for precision SAW based sensing is expensive. However, there is a need for disposable precise sensing and measurement that is not met by present day devices.

Electrical devices use connections for power or communications. Connections can be either wired or wireless. An example of a wired power connection is a household appliance, such as a lamp, plugged into a wall receptacle. An example of a wired signal connection is a headset plugged into an audio player. An example of a wireless connection over which power is transferred and signals are passed is given in U.S. Pat. No. 4,210,900. The use and placement of the connections has a tremendous effect on the unit cost of sensors. Many sensor modules include electrical circuitry for power, signal conditioning, and producing measurements. It is not economical for most entities, except for the richest, to treat sensor modules that include significant electrical circuitry as disposable. There are currently no SAW based flow sensors wherein the SAW substrate and transducers constitute a disposable sensor module and external electrical circuitry is retained.

Another advantage of SAW type devices is that they can store energy in the form of acoustic waves. A SAW can be energized by receiving power through a wired or wireless connection. If the power to the SAW is halted, then the SAW can continue to operate by using the stored energy. It will cease operation when the stored energy is depleted. This energy storage property is particularly useful is applications that use a wireless connection to supply power in the form of a radio frequency electromagnetic field. External circuitry can create a radio frequency electromagnetic field and thereby energize a SAW device. The external circuitry can then stop creating the field. The SAW device stops receiving energy, but continues to operate. Furthermore, the SAW device often creates a radio frequency electromagnetic field that can be sensed by external circuitry. In this manner, SAW devices can be powered and sensed via radio frequency electromagnetic fields.

The present invention directly addresses the shortcomings of the prior art by using SH-SAW and guided SH-SAW based sensor modules for measuring fluid flow. Furthermore, the connection between the external electronic circuitry and the SAW based sensor modules can be via a wired or a wireless connection.

### BRIEF SUMMARY

It is therefore one aspect of the embodiments to use a SH-SAW based sensor module to measure fluid flow. A substrate designed for SH mode propagation is used. A transducer converts an input electrical signal to an acoustic signal. The acoustic wave traverses the substrate to another transducer where it is converted into an electrical signal. A heater is also formed on the substrate. The heater is often made from a metal other than that used for the SAW transducers, requiring extra photolithographic processing. Furthermore, a heater is typically powered using a DC electric power source. The sensor module is powered and communicates with external electrical circuitry by way of a wired connection.

It is another aspect of the embodiments to use a SH-SAW based sensor module connected wirelessly to external circuitry for measuring fluid flow. A substrate designed for SH mode propagation is used. A transducer converts an input electrical signal to an acoustic signal. The acoustic wave traverses the substrate to another transducer where it is converted into an electrical signal. A heater is also formed on the substrate. The sensor module is powered and communicates with external electrical circuitry by way of a wireless connection.

It is a further aspect of the embodiments to make the heater from the same material as the transducers and form the heater during the same processing steps that form the transducers. Heaters are commonly made of a different material and are attached or formed in heater specific processing steps. The reason is that some materials make ideal heaters and others make ideal transducers. However, transducer material can be formed into an adequate heater with the advantage of reduced cost.

It is also another aspect of the embodiments to use the upstream SAW transducer, downstream SAW transducer, or both as a heater. This is possible because a SAW transducer reacts differently to different input signals. Some signals will be efficiently converted into acoustic signals. Other signals will not be. All signals carry energy. Electrical energy that enters a SAW transducer is converted into either acoustic energy or heat. A signal that is not efficiently converted into an acoustic signal causes the transducer to heat up. A SAW transducer can be supplied with many signals at the same time. If at least one of the signals is converted to heat, then the SAW transducer acts as a heater. The other signals can be efficiently converted into acoustic signals. The SAW transducer is therefore acting as both a transducer and a heater.

It is an additional aspect of the embodiments to configure a SH-SAW based pressure sensor module onto the substrate. A SH-SAW pressure sensor module has both an input transducer and an output transducer. Both transducers may be produced on the substrate using photolithographic processes. Furthermore, if the pressure sensor module is on the same substrate as a fluid flow sensor module, then the two modules can share at least one transducer. For example, the pressure sensor module's input transducer can also be the fluid flow sensor module's upstream transducer.

The defining characteristic of a SAW based pressure sensor is that pressure must affect at least one of the transducers. This is typically achieved by placing a transducer on an area of the substrate that is thinned enough that the thinned substrate acts as a diaphragm.

It is a yet further aspect of the embodiments to configure a SH-SAW based sensor module that detects chemicals or measures a chemical property onto the substrate. As before, an input and an output transducer are required. Also, as before, the chemical sensor module could share a transducer with other SH-SAW based sensors that are on the same substrate. Some chemical properties, such as the pH of a liquid, can be measured by exposing a SH-SAW transducer to the liquid. Other chemicals and properties are measured by placing a film on top of a transducer. The film is sensitive to certain chemicals in or properties of the fluid. Based on the fluid, the film exerts a force on the SH-SAW transducer, thereby changing its acousto-electric properties. SAW and SH-SAW based chemical sensors are known to those practiced in the art of SAW devices.

It is a still yet further aspect of the embodiments to use guided SH-SAW acoustic waves. A SH-SAW acoustic wave can be guided by depositing a film or layer of material over all or part of a SH-SAW based sensor module. The film acts to guide or confine the SH-SAW acoustic waves. The most important consideration is that the film should not improperly interfere with transducer operation. As mentioned previously, those skilled in the art of SAW devices are aware of the fabrication and properties of SH-SAW devices and guided SH-SAW devices.

### BRIEF DESCRIPTION OF THE DRAWINGS

The accompanying figures, in which like reference numerals refer to identical or functionally similar elements throughout the separate views and which are incorporated in and form a part of the specification, further illustrate the present invention and, together with the background of the invention, brief summary of the invention, and detailed description of the invention, serve to explain the principles of the present invention.

FIG. 1, labeled “prior art”, illustrates Rayleigh mode acoustic waves;

FIG. 2, labeled “prior art”, illustrates SH mode acoustic waves;

FIG. 3, labeled “prior art”, illustrates a SAW sensor module with serpentine transducers;

FIG. 4, labeled “prior art”, illustrates a SAW sensor module with interdigitated transducers;

FIG. 5 illustrates a SH-SAW based fluid flow sensor module in accordance with a preferred embodiment;

FIG. 6 illustrates a SH-SAW based fluid flow sensor module in accordance with a preferred embodiment;

FIG. 7 illustrates a film or layer over a substrate to produce a guided SH-SAW based device in accordance with a preferred embodiment;

FIG. 8 illustrates a SH-SAW based fluid flow sensor module in accordance with a preferred embodiment;

FIG. 9 illustrates a SH-SAW based fluid flow and pressure sensor module in accordance with a preferred embodiment;

FIG. 10 illustrates a SH-SAW based fluid flow, chemical and pressure sensor module in accordance with a preferred embodiment;

FIG. 11 illustrates a SH-SAW based fluid flow sensor module immersed in a flowing fluid inside a pipe in accordance with a preferred embodiment; and

FIG. 12 illustrates SH-SAW transducers that have dissimilar orientation in accordance with a preferred embodiment.

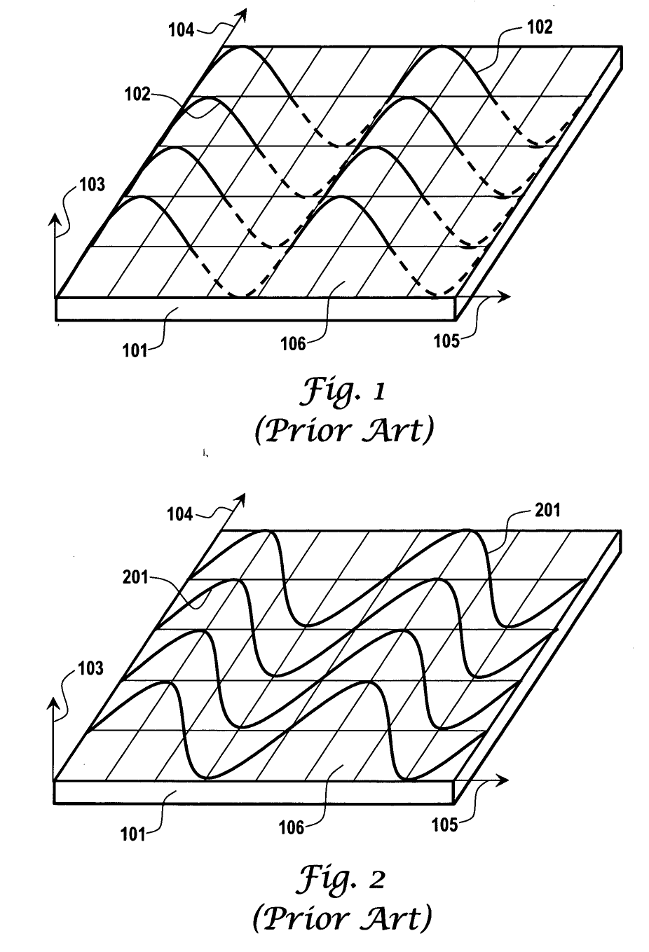

### DETAILED DESCRIPTION

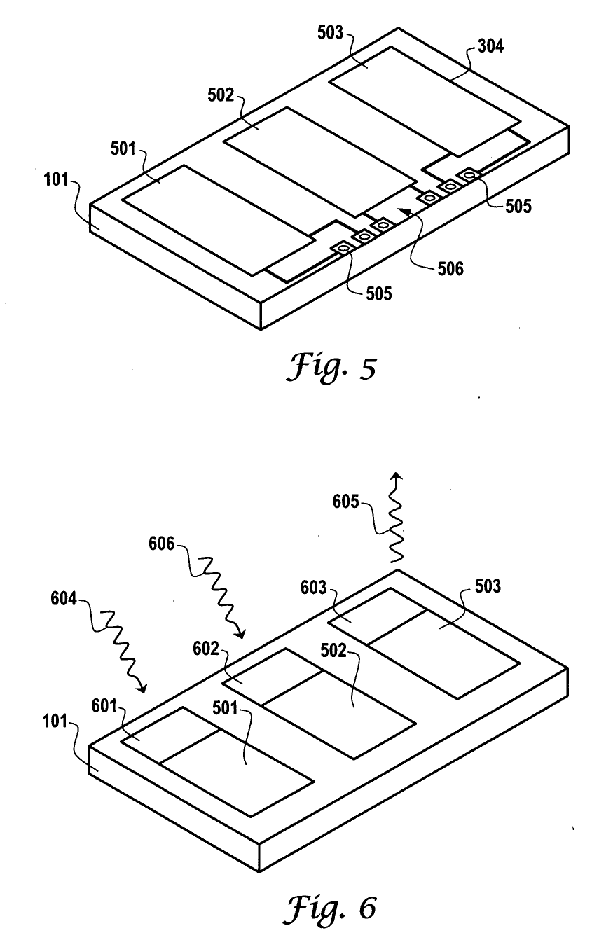

In accordance with an aspect, FIG. 5 shows a SH-SAW based fluid flow sensor module. An SH-SAW input transducer 501, SH-SAW output transducer 503, and heater 502 are on a substrate 101. A connection point 506 for wired connections also lies on the substrate 101. The connection point 506 shown here has 6 pads 505. The pads 505 are used for coupling signals into the input transducer 501, power into the heater 502, and signals out of the output transducer 503. External circuitry can be attached to the pads 505 by soldering on wires, friction connectors, or any of the other techniques known to those skilled in the art of electric circuitry.

In accordance with another aspect, the heater 502 is made from the same material and in the same processing steps as the SH-SAW transducers. This was discussed above.

In accordance with another aspect, FIG. 6 shows a SH-SAW based fluid flow sensor module that is wirelessly coupled to external circuitry. SAW input transducers typically convert a radio frequency input signal to an ultrasonic acoustic signal. As such, the input signal 604 can be transmitted wirelessly. The input transducer 501 of FIG. 6 is shown next to an input antenna 601. The input antenna 601 receives the input signal 604 and couples it into the input transducer 501. Alternatively, the input transducer 501 itself can act as an antenna. In this case, the input transducer 501 receives the input signal 604 and converts it to an acoustic signal. Similarly, SAW output transducers typically convert an ultrasonic signal into a radio frequency signal. The output transducer 503 of FIG. 6 is shown next to an output antenna 603. The output transducer 503 converts an acoustic signal into an electric signal and couples it into the output antenna 603 that transmits it as the output signal 605. The output transducer 503 can also act as an antenna. In this case the output transducer 503 receives the acoustic signal and converts it directly into the output signal 605.

In accordance with another aspect, the heater can be inductively powered. FIG. 6 shows a power signal 606 that is received by the heater antenna 602, coupled into the heater 502 and turned into heat. Alternatively, the heater 502 itself can be designed to also act as an antenna. In that case the power signal 606 is received by the heater 502 and transformed into heat.

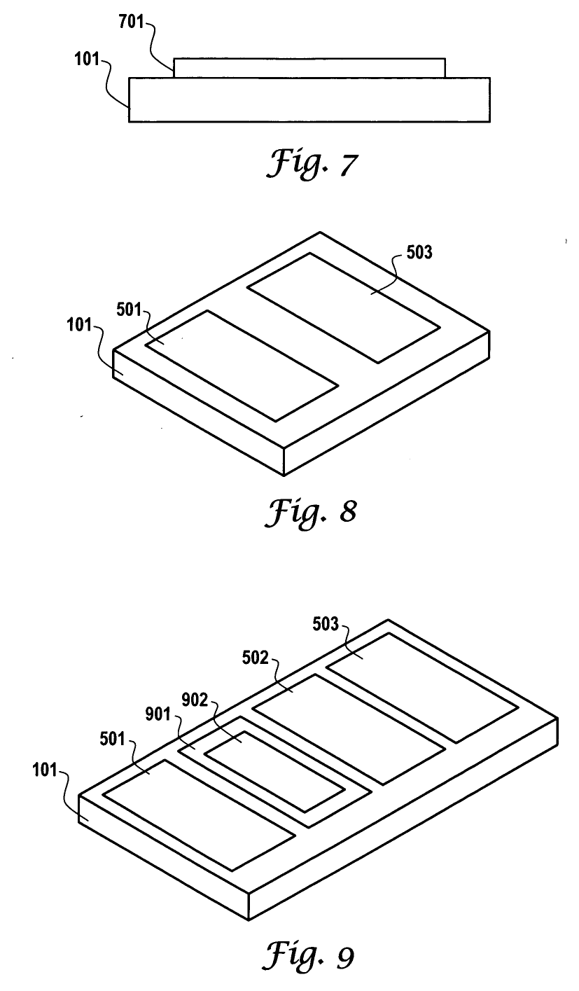

In accordance with another aspect, FIG. 7 shows a side view of substrate with a thin film or layer of material on it. The purpose of the illustration is to show how easily a SH-SAW based device can be converted into a guided SH-SAW based device. Most SH-SAW based sensors, sensor modules, or other devices, including those exhibiting the aspects discussed herein, can be easily implemented as guided SH-SAW devices.

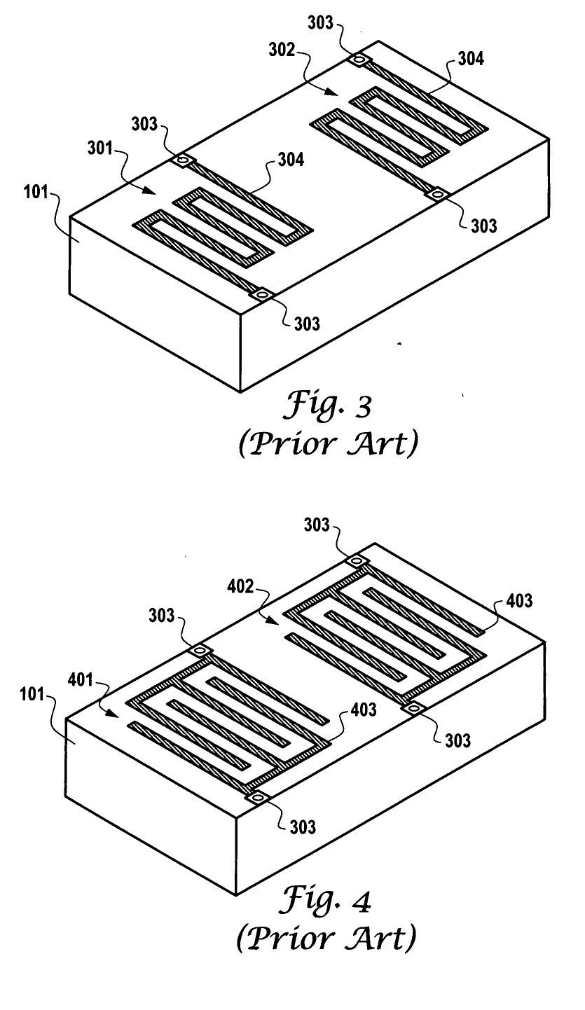

In accordance with another aspect, FIG. 8 shows a SH-SAW based device wherein either transducer, or both, also functions as a heater. The input transducer 501 and the output transducer 503 are on the substrate 101. A transducer can act as a heater if it is designed with low equivalent circuit resistance such that the high current flow through it causes it to heat up instead of causing it to produce an acoustic signal or an electromagnetic signal. For example, the serpentine transducer 304 of FIG. 3 will produce heat from either a DC current or very low frequency signal. Note that a DC current is also a zero hertz signal. The connection to external circuitry is not shown in FIG. 8 because either a wired or wireless connection can be used. If a wireless connection is used, an antenna, similar to power antenna 602, may be required.

In accordance with another aspect, FIG. 9 shows an SH-SAW based sensor module similar to that of FIG. 5 with the addition of a pressure sensor. A diaphragm 901 is formed into the substrate by thinning the substrate in a small region. Usually, the thinning is done from the side opposite that on which the transducers lie. A pressure output transducer 902 is formed on the diaphragm. The use of the same substrate 101 for pressure sensing and fluid flow sensing results in a cost saving.

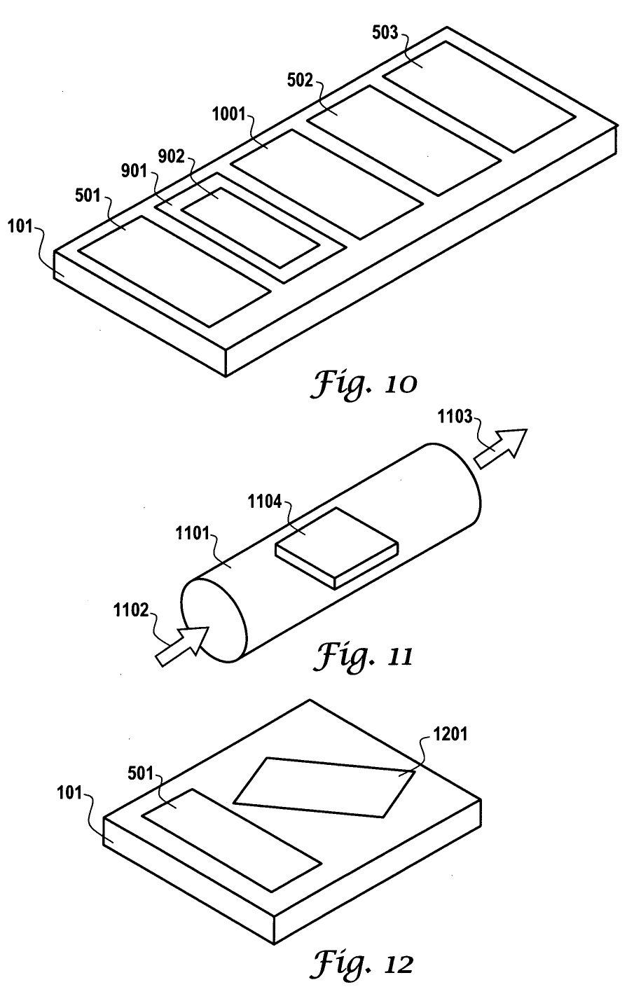

In accordance with another aspect, FIG. 10 shows an SH-SAW based sensor module similar to that of FIG. 9 with the addition of a chemical sensor. A chemical output transducer 1001 is formed on the substrate. The use of the same substrate 101 for pressure sensing, chemical sensing, and fluid flow sensing results in a cost saving.

FIG. 9 and FIG. 10 show combinations of different sensor types on a single substrate. Many other combinations are possible. For example, fluid flow and chemical can be combined. Alternatively, more than one chemical sensor can be combined where the different chemical sensors can be sensitive to different chemicals or chemical properties. Finally, the figures do not show the connection to external circuitry because either a wired or wireless connection can be used.

FIG. 11 shows a SH-SAW based sensor module 1104 inside of a conduit 1101. Fluid 1102 enters the conduit 1101 flows past the SH-SAW based sensor module 1104, and exits the conduit 1103. Here, the connection to the external circuitry is wireless because the signals can be transmitted through the sides of many conduit or pipes. This facilitates the use and deployment of disposable sensor modules. For example, the disposable unit could be a length of conduit, pipe or tubing with a flow sensor mounted inside it. The external circuitry can remain while the disposable portion can be regularly changed as part of a maintenance routine.

In accordance with another aspect, FIG. 12 shows an input transducer 501 and an output transducer 1201 on a substrate 101. Here the two transducers do not have the same orientation. The purpose of the FIG. 12 is to show that all of the transducers and heaters in a SH-SAW based sensor module can have different orientations.

It will be appreciated that variations of the above-disclosed and other features, aspects and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A fluid flow sensor module comprising:
A substrate;
an input SH-SAW transducer mounted on the substrate;
a heater that heats the substrate;
an output SH-SAW transducer mounted on the substrate; and
a connection that transfers power, the input signal, and the output signal between the fluid flow sensor module and outside circuitry.

2. The fluid flow sensor module of claim 1 wherein the connection is wireless.

3. The fluid flow sensor module of claim 2 further comprising a film or layer for producing guided SH-SAW acoustic waves.

4. The fluid flow sensor module of claim 3 wherein the heater comprises the same materials as the transducers.

5. The fluid flow sensor module of claim 4 wherein the input SH-SAW transducer, output SH-SAW transducer, or both is also the heater.

6. The fluid flow sensor module of claim 1 further comprising a SAW based pressure sensor.

7. The fluid flow sensor module of claim 1 further comprising a SAW based chemical sensor.

8. A fluid flow sensor module comprising:
a conduit;
a substrate mounted inside the conduit;
an input SH-SAW transducer mounted on the substrate;
a heater that heats the substrate;
an output SH-SAW transducer mounted on the substrate; and
a connection that transfers power, the input signal, and the output signal between the fluid flow sensor and outside circuitry.

9. The fluid flow sensor module of claim 8 wherein the connection is wireless.

10. The fluid flow sensor module of claim 9 further comprising a film or layer for producing guided SH-SAW acoustic waves.

11. The fluid flow sensor module of claim 10 wherein the heater comprises the same materials as the transducers.

12. The fluid flow sensor module of claim 11 wherein the input SH-SAW transducer, output SH-SAW transducer, or both is also the heater.

12. The fluid flow sensor module of claim 8 wherein the heater comprises the same materials as the transducers.

13. The fluid flow sensor module of claim 8 further comprising a SAW based pressure sensor.

14. The fluid flow sensor module of claim 8 further comprising a SAW based chemical sensor.

15 A method of measuring fluid flow using a substrate on which are mounted an input SH-SAW device, a heater, and an output SH-SAW device;
placing the substrate into a flowing fluid such that the direction of flow carries the fluid from the upstream SH-SAW transducer toward the downstream SH-SAW transducer;
supplying power to the heater;
supplying an input signal to one SH-SAW transducer;
obtaining an output signal from the other SH-SAW transducer; and
processing the input signal and the output signal to yield a measurement indicative of the fluid flow rate.

16. The method of claim 15 wherein the guided SH-SAW acoustic waves are used.

17. The method of claim 16 wherein the heater is a SH-SAW transducer.

18. The method of claim 17 wherein the upstream SH-SAW transducer, downstream SH-SAW transducer, or both is also the heater.

19. The method of claim 15 wherein the heater is a SH-SAW device.

20. The method of claim 15 further comprising using SAW based pressure sensor to measure the fluid's pressure.

21. The method of claim 15 further comprising a using a SAW based chemical sensor that is sensitive to the presence of certain chemicals to sense the presence of those chemicals.
